(19) United States
(12) Patent Application Publication
(10) Pub. No.: US 2019/0023619 A1
(43) Pub. Date: Jan. 24, 2019

(54) COPPER-CERAMIC COMPOSITE

(71) Applicant: Heraeus Deutschland GmbH & Co. KG, Hanau (DE)

(72) Inventors: KAI Herbst, Erlangen (DE); Christian Muschelknautz, Darmstadt (DE)

(21) Appl. No.: 16/078,235

(22) PCT Filed: Feb. 16, 2017
(86) PCT No.: PCT/EP2017/053449

§ 371 Date: Aug. 21, 2018

(30) Foreign Application Priority Data
Feb. 26, 2016 (DE) 10 2016 203 058.2

(51) Int. Cl. C04B 37/02; H05K 3/38; B32B 15/20; H01L 23/373

(52) U.S. Cl. CPC C04B 37/021; H05K 3/38; B32B 15/20; C04B 2237/706; C04B 2235/782; C04B 2235/786; C04B 2237/704; H01L 23/3735

(57) ABSTRACT

The present invention relates to a copper-ceramic composite comprising—a ceramic substrate which contains aluminum oxide, the aluminum oxide having particle sizes in the range of 0.01 μm to 25 μm and a quantity distribution of the particle sizes with a median value d₅₀ and an arithmetic mean value dₐᵣᵢₜₕ, and the ratio of d₅₀ to dₐᵣᵢₜₕ being in the range of 0.75 to 1.10, —a coating made of copper or a copper alloy provided on the ceramic substrate.

The present invention relates to a copper-ceramic composite and also a module which contains this composite and can be used in power electronics components.

Ceramic circuit supports are of particular interest in the field of high-power electronics because of their high thermal conductivity, high dimensional stability or mechanical strength and also their high insulation strength.

Various processes such as direct copper bonding (usually referred to as DCB process) or active metal brazing (usually referred to as AMB process) are available for metallizing a ceramic substrate.

The composite material obtained after metallization of the ceramic substrate is also referred to as metal-ceramic substrate or metal-ceramic composite. If it has, for example, been produced by a DCB process, the term “DCB substrate” is frequently also used.

The DCB process exploits the fact that oxygen reduces the melting point of copper of 1083° C. to the eutectic melting point of 1065° C. The oxidation of copper foils before metallization of the ceramic substrate or introduction of oxygen during the high-temperature process (for example at a temperature in the range from 1065° C. to 1080° C.) forms a thin eutectic melt layer. This reacts with the surface of the ceramic substrate, so that ceramic and metal can be bonded firmly to one another.

DCB processes are described, for example, in U.S. Pat. No. 3,744,120 or DE 23 19 854.

The metallization can, for example, be carried out on only one side of the ceramic substrate (“single layer bonding” SLB) or as an alternative simultaneously on both sides of the ceramic substrate (“double layer bonding” DLB). It is also possible firstly to metallize a first side of the substrate by means of a first SLB step and subsequently also metallize the opposite side of the substrate in a further SLB step.

Structuring the applied metal coating for the formation of conductor tracks, for example by etching processes, is also known.

In many applications of power electronics, the metal-ceramic composite is subjected to high temperature-change stresses, in the case of which significant temperature changes (e.g. in the range from −40° C. to +150° C.) can occur.

Due to the different coefficients of thermal expansion of the ceramic substrate and of the metal coating, considerable mechanical stresses arise at the transition between these layers in the event of temperature fluctuations, and these can ultimately lead to at least partial detachment of the metal from the ceramic surface. It is known that a specific structuring of the metal layer on a macroscopic level in its peripheral region can reduce tensile and compressive stresses and thus improve the thermal shock resistance. DE 40 04 844 A1 and DE 43 18 241 A1 describe metal coatings on ceramic substrates, which coatings have peripheral weakenings in the form of depressions or holes at their edges.

The temperature-change stresses occurring in operation can lead to cracking in the ceramic. Moreover, during transport or during installation into an electronic component, mechanical stresses may occur that likewise cause cracking in the ceramic.

In order as far as possible to minimize cracking in the ceramic as a consequence of temperature-change stresses or other mechanical stresses, the ceramic substrate of the metal-ceramic composite ought to have a very high mechanical strength (for example in the form of a very high flexural fracture strength).

In operation, the structured metal coating makes contact with electronic components such as chips, for example. In the areas of these electronic components, there may be considerable evolution of heat. This heat ought to be dissipated as rapidly as possible via the ceramic substrate.

In principle, therefore, it is desirable for the ceramic substrate to have not only good mechanical strength but also very high thermal conductivity. In actual practice, however, it proves to be difficult to optimize both properties at the same time. The improvement in one parameter is frequently achieved at the expense of the other parameter.

Further relevant properties of a copper-ceramic composite for applications in electronics are also high temperature change resistance, very strong bonding of the metal coating to the ceramic surface, wherein this bond should remain sufficiently strong even under prolonged temperature change stresses, and good bonding behavior of the copper coating in respect of bonding wires.

In DE 10 2012 110 322, the ceramic substrate of the metal-ceramic composite is defined in more detail in respect of its grain structure (i.e. its structure on a microscopic level). The ceramic substrate contains an aluminum oxide reinforced with zirconium oxide, with the average grain size of the aluminum oxide being in the range of 2-8 μm and the ratio of the length of the grain boundaries of Al₂O₃ grains to the total length of all grain boundaries being >0.6. According to DE 10 2012 110 322, this grain structure contributes to improving the thermal conductivity.

It is an object of the present invention to provide a metal-ceramic composite having an improved property profile, in particular high mechanical strength and high thermal conductivity.

The object is achieved by a copper-ceramic composite comprising
a ceramic substrate containing aluminum oxide,
a coating composed of copper or a copper alloy present on the ceramic substrate,
   wherein the aluminum oxide has grain sizes in the range from 0.01 μm to 25 μm.

The ceramic substrate of a copper-ceramic composite is generally a polycrystalline material consisting of small crystallites (which are also referred to as grains). On a microscopic level, polycrystalline materials can be characterized in more detail in terms of their grain structure (e.g. grain size distributions, shape of the grains, texture, . . . etc.).

In the context of the present invention it has been ascertained that a ceramic substrate which comprises aluminum oxide (Al₂O₃) having grain sizes in the range of 0.01 μm to 25 μm exhibits both high mechanical strength and high thermal conductivity.

An improvement in mechanical strength is manifested in particular in an improved flexural fracture strength. According to the invention, an improved flexural fracture strength of the ceramic means that the force leading to fracture in a three-point bending test is increased. An example of a flexural fracture strength determination of the ceramic will be known to a person skilled in the art from DIN EN 843-1 (2008). The specimen geometry preferably deviates from that in DIN EN 843-1 (2008) in that the specimens have dimensions of 20×40×0.38 mm³ or 20×40×0.63 mm³.

According to the invention, thermal shock resistance is the resistance or the resistance capability of the copper layer to delamination from the ceramic of a copper-ceramic substrate, with the resistance being determined subsequent to at least one temperature change of the copper layer relative to the ceramic. An improved thermal shock resistance means that the number of temperature changes withstood increases.

According to the invention, improved wire bonding means that the force required to detach the bond wire from the copper surface of a copper-ceramic composite is increased.

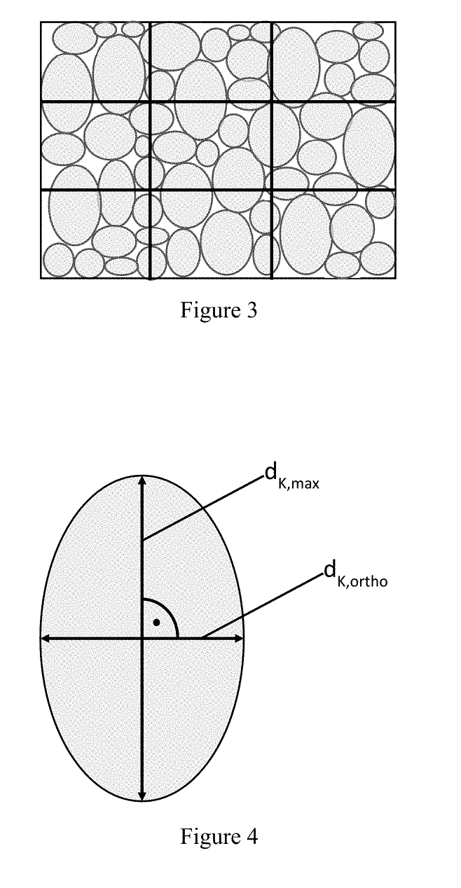

According to the invention, an improved copper adhesion strength is an adhesive strength of the copper relative to the copper-ceramic composite, so that the force required to detach the bonded copper foil from the ceramic surface of a copper-ceramic composite is increased. An illustrative measurement method is known to a person skilled in the art from DE102004012231B4 (FIGS. 2 and 3 of DE102004012231B4).

The grain sizes of the aluminum oxide are preferably in the range from 0.3 μm to 23 μm, even more preferably in the range from 0.5 μm to 20 μm.

In the context of the present invention, these values should not be regarded as strict lower and upper limits for the grain size distribution, but can instead vary by +/−10%. However, in a preferred embodiment, these values are the lower limit, below which the grain size does not go, and upper limit, which is not exceeded, of the grain size distribution of the aluminum oxide. In this preferred embodiment, the aluminum oxide therefore does not have any grains which lie outside the abovementioned ranges. Thus, it is preferred that dₘᵢₙ(Al₂O₃) is ≥0.01 μm and dₘₐₓ(Al₂O₃) is ≤25 μm, more preferably dₘᵢₙ(Al₂O₃) is ≥0.3 μm and dₘₐₓ(Al₂O₃) is ≤23 μm, even more preferably dₘᵢₙ(Al₂O₃) is ≥0.5 μm and dₘₐₓ(Al₂O₃) is ≤20 μm, where dₘᵢₙ(Al₂O₃) and dₘₐₓ(Al₂O₃) are the minimum and maximum grain sizes of the aluminum oxide.

Use of a ceramic starting material having a suitable Al₂O₃ grain size distribution enables the desired Al₂O₃ grain sizes in the copper-ceramic composite to be set. Such ceramic materials are commercially available or can be obtained by standard methods. Fine adjustment of the grain sizes can optionally be effected by thermal treatment of the ceramic starting material.

As is known in principle to a person skilled in the art, the determination of the grain size distribution can be carried out on the basis of the number of grains (i.e. number distribution) or alternatively on the basis of the mass (i.e. mass distribution) or the volume of the grains. For the purposes of the present invention, the distribution of the grain sizes is determined on the basis of the number of grains.

In a preferred embodiment, the aluminum oxide of the ceramic substrate has a number distribution of the grain sizes in which not more than 5% of the grains have a grain size of less than 0.1 μm, more preferably less than 0.3 μm, even more preferably less than 0.5 μm; and/or in which at least 95% of the grains have a grain size of less than 15 μm, more preferably less than 10 μm, even more preferably less than 7 μm.

As is generally known, characteristic values of a grain size distribution are, inter alia, the d₅₀, the d₅ and the d₉₅ thereof. The d₅₀, which is frequently also referred to as median value, is defined as follows: 50% of the grains have a diameter which is smaller than the d₅₀. Analogously, the d₅ is such that 5% of the grains have a diameter which is smaller than this d₅, and the d₉₅ is such that 95% of the grains have a diameter which is smaller than this d₉₅.

The arithmetic mean dₐᵣᵢₜₕ of a grain size distribution is the sum of the grain sizes of the individual grains divided by the number of grains. The symmetry of a grain size distribution can be expressed by the ratio of the median d₅₀ to the arithmetic mean dₐᵣᵢₜₕ of this distribution (i.e. by the ratio d₅₀/dₐᵣᵢₜₕ; hereinafter also referred to as symmetry value of a grain size number distribution). The closer the value of this ratio is to 1.0 the more symmetric is the grain size distribution.

As has surprisingly been ascertained in the context of the present invention, a further optimization of the mechanical strength and of the thermal conductivity can be achieved if the grain size distribution of the aluminum oxide in the ceramic substrate is as far as possible symmetric. In one preferred embodiment, therefore, the Al₂O₃ of the ceramic substrate has a number distribution of the grain sizes with a median value d₅₀ and an arithmetic mean dₐᵣᵢₜₕ where the ratio of d₅₀ to dₐᵣᵢₜₕ (i.e. d₅₀/dₐᵣᵢₜₕ) is in the range from 0.75 to 1.10, more preferably in the range from 0.78 to 1.05, even more preferably in the range from 0.80 to 1.00.

Suitable methods by means of which the symmetry of the grain size distribution of the aluminum oxide can be adjusted, for example already in the production of the starting substrate, are known to those skilled in the art. For example, the symmetry of the grain size distribution can be influenced by sintering time and sintering temperature in the production of the starting substrate. Al₂O₃ substrates by means of which the abovementioned symmetry values can be realized in the final copper-ceramic composite are commercially available or can be obtained by standard methods.

It has surprisingly been ascertained that further optimization of mechanical strength and of the thermal conductivity can be achieved if the breadth of the grain size distribution of the aluminum oxide satisfies certain conditions. If too narrow a grain size distribution is selected, there may be deleterious consequences for the thermal conductivity, whereas too broad a grain size distribution may be deleterious for the mechanical strength. The breadth of the grain size distribution can be expressed by the ratio of d₅ to d₉₅. In a preferred embodiment, the aluminum oxide has a number distribution of the grain sizes having a d₅ and a d₉₅ such that the ratio of d₅ to d₉₅ is in the range from 0.1 to 0.4, more preferably in the range from 0.11 to 0.35, even more preferably in the range from 0.12 to 0.30.

The number distribution of the grain sizes of the aluminum oxide preferably has a d₉₅ of ≤15.0 μm, more preferably in the range from 4.0 μm to 15.0 μm, even more preferably in the range from 4.5 μm to 10.0 μm, still more preferably in the range from 5.0 μm to 8.0 μm. The d₅ of the grain size number distribution of the aluminum oxide is preferably ≥0.1 μm; d₅ is more preferably in the range from 0.1 μm to 2.5 μm, even more preferably in the range from 0.3 μm to 2.5 μm, still more preferably in the range from 0.5 μm to 2.0 μm.

A preferred d₅₀ of the grain size number distribution of the aluminum oxide is, for example, in the range from 1.0 μm to 3.0 μm.

For the purposes of the present invention, it can be preferred that the d₅, d₉₅ and d₅₀ values of the grain size number distribution of the aluminum oxide are selected so that they satisfy the following condition:

9.5≥(d₉₅−d₅)/d₅₀≥0.7

A further optimization of the mechanical strength can be achieved if the grains of the aluminum oxide, in their two-dimensional projection in a plane parallel to the surface of the ceramic substrate, have a shape which is as far as possible circular or round. The shape of an individual Al₂O₃ grain can be expressed by way of its shape factor R_{K} which is the ratio of the maximum grain diameter d_{K,max} to the grain diameter d_{K,ortho}, which runs perpendicular to d_{K,max}, determined at half the length of d_{K,max} (i.e. R_{K}=d_{K,ortho}/d_{K,max}).

From the arithmetic mean of the shape factors R_{K} of the Al₂O₃ grains, the average grain shape factor Rₐ(Al₂O₃) of the aluminum oxide is obtained. Where, for example, an aluminum oxide material includes a high fraction of elongate grains, the average grain shape factor of this copper will have a relatively low value. On the other hand, the closer the average grain shape factor to a value of 1.0, the higher the fraction of relatively round, circular grains.

The average grain shape factor Rₐ(Al₂O₃) of the aluminum oxide is preferably ≥0.40, even more preferably ≥0.60 or ≥0.80. Suitable methods by means of which the shape of the aluminum oxide grains can be set, for example already in the production of the starting substrate, are known to those skilled in the art. For example, the shape of the Al₂O₃ grains can be influenced by sintering time and sintering temperature in the production of the starting substrate. Al₂O₃ substrates by means of which the abovementioned shape factor Rₐ(Al₂O₃) can be realized in the final copper-ceramic composite are commercially available or can be obtained by standard methods.

A suitable thickness of the ceramic substrate in a copper-ceramic composite is known to those skilled in the art. The ceramic substrate usually has a thickness in the range of 0.2-1.2 mm over at least 70% of its area, more preferably at least 90% of its area. A thickness of the ceramic substrate is, for example, about 0.38 mm or about 0.63 mm.

The thickness of the ceramic substrate (D_{cer}) and the median d₅₀ of the grain size number distribution of the aluminum oxide in the ceramic substrate are preferably selected so that the ratio D_{cer} to d₅₀ (i.e. D_{cer}/d₅₀) is in the range from 0.001 to 0.01, more preferably in the range from 0.002 to 0.009, even more preferably in the range from 0.004 to 0.008. For this purpose, the thickness D_{cer} of the ceramic substrate is determined at one place and divided by the median d₅₀ of the grain size number distribution of the aluminum oxide. The ratio D_{cer}/d₅₀ is preferably in the range from 0.05 to 0.40 over at least 70%, more preferably at least 90%, of the area of the ceramic substrate.

The aluminum oxide can optionally be reinforced with zirconium oxide (ZrO₂). Such ZrO₂-reinforced Al₂O₃ usually contains, based on its total mass, the zirconium oxide in a proportion of 0.5-30% by weight. The zirconium oxide can in turn optionally be doped with one or more doping oxide(s), in particular yttrium oxide, calcium oxide, cerium oxide or magnesium oxide, usually in a proportion of up to 0.01% by weight or even up to 5% by weight, based on the total mass of zirconium oxide and aluminum oxide.

The ceramic substrate preferably contains at least 65% by weight of Al₂O₃. If there is no ZrO₂ present for reinforcing the Al₂O₃, the ceramic substrate may contain at least 95% by weight, preferably 96% by weight, of Al₂O₃.

If a ZrO₂-reinforced aluminum oxide is used (where the ZrO₂ is, as mentioned above, optionally doped), the ceramic substrate may contain at least 96% by weight, more preferably at least 98% by weight, of this ZrO₂-reinforced Al₂O₃.

The ceramic substrate can, for example, have a thermal conductivity of ≥20 W/mK, and/or a flexural fracture strength of ≥400 MPa.

The ceramic substrate can be present in the form of an individual substrate. As an alternative, it is also possible for the ceramic substrate to have one or more (preferably linear) preferential fracture lines which divide the ceramic substrate into two or more regions and a metal coating (e.g. a coating composed of copper or a copper alloy) is applied at least in one of these regions. As regards the structure of such a multiple substrate with preferential fracture lines, reference may be made, for example, to DE 43 19 944 A1 and DE 199 27 046 A1.

Suitable dimensions (length×width) of the ceramic substrate (either as individual substrate or as multiple substrate) in a metal-ceramic composite are known to those skilled in the art. For example, the ceramic substrate can have dimensions, length×width, of (180-200 mm)×(130-150 mm) or (180-200 mm)×(270-290 mm). Smaller dimensions, for example (8-12 mm)×(8-12 mm), are also possible.

As mentioned above, there is a coating of copper or copper alloy on the ceramic substrate.

For the metallization of a ceramic substrate there are various processes available, such as, for example direct copper bonding (typically referred to as DCB process) or active metal brazing (typically referred to as AMB process).

The grain sizes of the copper or of the copper alloy are preferably in the range of 10 μm to 300 μm, more preferably in the range from 15 μm to 250 μm, even more preferably in the range from 20 μm to 210 μm. In this grain size range, the copper or the copper alloy displays good adhesion to a ceramic substrate even when the copper-ceramic composite is subjected to many temperature change stresses. At the same time, the copper or the copper alloy makes efficient wire bonding possible at these grain sizes. A metal coating displays good wire bonding when a very strong bond to a bond wire can be formed and the risk of undesirable detachment of the bond wire is thereby minimized. In the context of the present invention, these values should not be regarded as strict upper and lower limits for the grain size distribution, but instead can vary by +/−10%. However, in a preferred embodiment, these values are the lower limit, below which the grain size does not go, and upper limit, which is not exceeded, of the grain size distribution of the copper or of the copper alloy. In this preferred embodiment, the copper or the copper alloy therefore has no grains which are outside the abovementioned ranges. Preference is thus given to dₘᵢₙ(Cu) being ≥10 μm and dₘₐₓ(Cu) being ≤300 μm, more preferably dₘᵢₙ(Cu) being ≥15 μm and dₘₐₓ(Cu) being ≤250 μm, even more preferably dₘᵢₙ(Cu) being ≥20 μm and dₘₐₓ(Cu) being ≤210 μm, where dₘᵢₙ(Cu) and dₘₐₓ(Cu) are the minimum and maximum grain sizes of the copper.

Use of a copper starting foil having a suitable grain size distribution enables the desired grain sizes in the copper-ceramic composite to be set. Such copper foils are commercially available or can be obtained by standard methods. A fine adjustment of the grain sizes can optionally be effected by thermal treatment of the starting foil.

In a preferred embodiment, the copper or the copper alloy has a number distribution of the grain sizes in which not more than 5% of the grains have a grain size of less than 15 μm, preferably less than 20 μm, more preferably less than 25 μm; and/or in which at least 95% of the grains have a grain size of less than 250 μm, preferably less than 230 μm, more preferably less than 200 μm.

The number distribution of the grain sizes of the copper or of the copper alloy preferably has a d₉₅ of ≤250 μm, more preferably in the range from 140 μm to 250 μm, even more preferably in the range of 140 μm to 230 μm, still more preferably in the range of 150 μm to 200 μm. The d₅ of the grain size number distribution of the copper or of the copper alloy is preferably ≥15 μm; the d₅ is more preferably in the range from 15 μm to 80 μm, even more preferably in the range from 20 μm to 75 μm, still more preferably in the range of 25 μm to 70 μm. Further optimization of the thermal shock resistance and the bonding behavior of the copper or of the copper alloy can be achieved in this way.

A preferred d₅₀ of the grain size number distribution of the copper or of the copper alloy is, for example, in the range from 55 μm to 115 μm.

For the purposes of the present invention, it can be preferred that the d₅, d₉₅ and d₅₀ values of the grain size number distribution of the copper or of the copper alloy are selected so that they satisfy the following condition:

4.0≥(d₉₅−d₅)/d₅₀≥0.5

In a preferred embodiment, the copper or the copper alloy has a number distribution of the grain sizes having a median value d₅₀ and an arithmetic mean dₐᵣᵢₜₕ where the ratio of d₅₀ to dₐᵣᵢₜₕ (i.e. d₅₀/dₐᵣᵢₜₕ; also referred to below as symmetry value S(Cu) of the grain size number distribution of the copper or of the copper alloy) is in the range from 0.75 to 1.10, more preferably in the range from 0.78 to 1.05, more preferably still in the range from 0.80 to 1.00. Further optimization of the thermal shock resistance and the wire bonding properties can be achieved in this way. Suitable methods by means of which the symmetry of the grain size distribution in the copper, for example already in the copper starting foil, can be set are known to those skilled in the art. For example, the symmetry of the grain size distribution in a copper foil can be influenced by a suitable processing temperature or a rolling process. Copper starting foils by means of which the abovementioned symmetry values can be realized in the final copper-ceramic composite are commercially available or can be obtained by standard methods.

In a preferred embodiment, the copper or the copper alloy has a number distribution of the grain sizes having a d₅ and a d₉₅ where the ratio of d₅ to d₉₅ is in the range from 0.1 to 0.4, more preferably in the range from 0.11 to 0.35, even more preferably in the range from 0.12 to 0.30. Further optimization of the thermal shock resistance and the wire bonding properties can be achieved in this way.

The average grain shape factor Rₐ(Cu) of the copper or of the copper alloy is preferably ≥0.40, even more preferably ≥0.60 or ≥0.80. As mentioned above, the shape of an individual grain can be expressed by its shape factor R_{K} which is the ratio of the maximum grain diameter d_{K,max} to the grain diameter d_{K,ortho} running perpendicular to d_{K,max}, determined on half the length of d_{K,max} (i.e. R_{K}=d_{K,ortho}/d_{K,max}). The average grain shape factor Rₐ(Cu) of the copper is obtained from the arithmetic mean of the shape factors R_{K} of the grains. Suitable methods by means of which the shape of the grains in the copper, for example as early as in the copper starting foil, can be set are known to those skilled in the art. For example, the grain shape in a copper foil can be influenced by a suitable processing temperature or a rolling process. Copper starting foils by means of which the abovementioned average grain shape factor Rₐ(Cu) can be realized in the final copper-ceramic composite are commercially available or can be obtained by standard methods.

A suitable thickness of the coating composed of copper or of a copper alloy in a copper-ceramic composite is known to those skilled in the art. As explained below, part of the copper or of the copper alloy can be removed again at some places in the coating, in particular in peripheral regions, for example to form peripheral weak points. It is therefore possible in the context of the present invention for the thickness of the metal coating to vary. The coating composed of copper or a copper alloy usually has a thickness in the range of 0.2-1.2 mm over at least 70% of its area. For example, it is possible for the thickness to be about 300 μm.

The thickness of the coating composed of copper or a copper alloy (D_{Cu}) and the median d₅₀ of the grain size number distribution of the copper or of the copper alloy are preferably selected so that the ratio D_{Cu} to d₅₀ is in the range from 0.05 to 0.40. For this purpose, the thickness D_{Cu} of the copper or of the copper alloy is determined at one place in the coating and is divided by the median d₅₀ of the grain size number distribution of the copper or of the copper alloy. The ratio D_{Cu}/d₅₀ is preferably in the range from 0.05 to 0.40 over at least 70%, more preferably at least 90%, of the area of the coating composed of copper or a copper alloy.

The copper of the coating preferably has a purity of ≥99.50%, more preferably ≥99.90%, even more preferably ≥99.95% or even ≥99.99%.

The coating composed of copper or a copper alloy is preferably applied by means of a DCB process to the ceramic substrate. As indicated above, a customary DCB process can, for example, have the following process steps:
Oxidizing a copper foil so that a copper oxide layer is formed on the surface thereof;
Laying the copper foil with the copper oxide layer on the ceramic substrate;
Heating the composite to a temperature of <1083° C. (e.g. a temperature in the range of 1065-1080° C.),
Cooling to room temperature.

As a result of the DCB process, spinel crystallites (e.g. copper-aluminum spinels) can be present between the coating composed of copper or a copper alloy and the ceramic substrate.

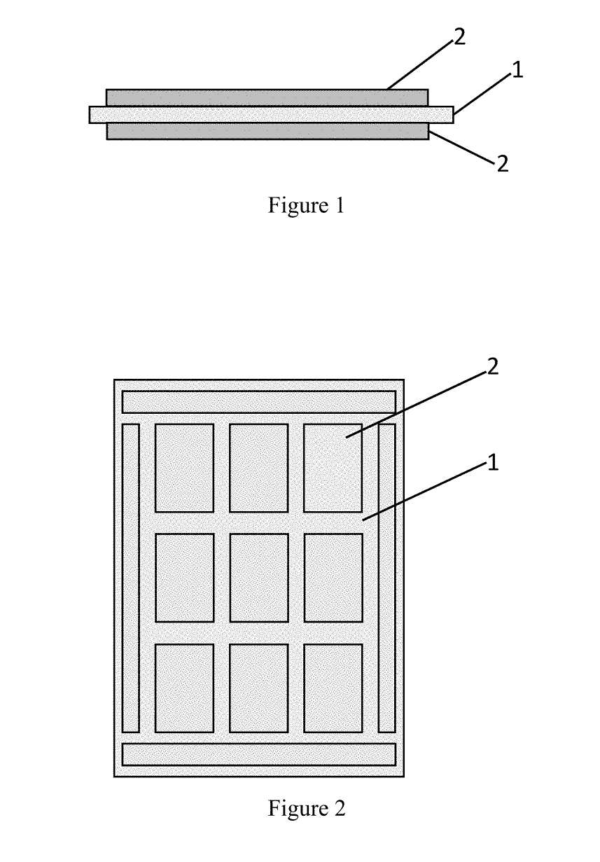

The coating composed of copper or a copper alloy can, for example, have been applied to only one side of the ceramic substrate. As an alternative, it is possible for both sides (i.e. upper side and underside) of the ceramic substrate to have been provided with the coating composed of copper or a copper alloy. An illustrative copper-ceramic composite in which a ceramic substrate 1 has a coating 2 composed of copper or a copper alloy both on its underside and also on its upper side is shown in FIG. 1. An illustrative copper-ceramic composite in which the ceramic substrate 1 has a plurality of regions which are each provided with a coating 2 composed of copper or copper alloy is shown in FIG. 2. As explained below, the individual metallized regions can be separated from one another by preferential fracture lines (not shown in FIG. 2), so that these regions can be individualized by breaking along these preferential fracture lines.

To form electrical contact areas, the coating composed of copper or a copper alloy can at least partly have structuring. The structuring of the metal coating can be carried out in a known manner, in particular by means of an etching process (for example using an etching mask).

In the etching process, the copper or the copper alloy can be removed completely in subregions, so that the surface of the ceramic substrate is exposed in these subregions. Furthermore, it is also possible for the coating composed of copper or a copper alloy to have one or more depressions (preferably round depressions) which might be obtained in the etching process by the copper or the copper alloy being only partially removed in the region of the depression to be introduced and the surface of the ceramic substrate therefore still being coated with copper or copper alloy in this region. As an alternative or in addition, it is possible to etch the depressions through the copper or the copper alloy through to the ceramic surface. As regards the possible arrangement of such depressions, preferably in the peripheral region of the coatings composed of copper or copper alloy, reference may be made, for example, to DE 40 04 844 C1 and DE 43 18 241 A1.

A further improvement in the properties of the copper-ceramic composite can be realized if the grain properties of the copper or of the copper alloy and the grain properties of the aluminum oxide in the ceramic substrate are harmonized with one another.

In a preferred embodiment, the ratio of d₅₀(Al₂O₃) to d₅₀(Cu) is in the range from 0.008 to 0.055, more preferably in the range from 0.010 to 0.045. Further optimization of the copper-ceramic adhesion and thermal shock resistance in the copper-ceramic composite can be achieved in this way.

In a preferred embodiment, the copper or the copper alloy has a number distribution of the grain sizes having a median d₅₀, an arithmetic mean dₐᵣᵢₜₕ and a symmetry value S(Cu)=d₅₀/dₐᵣᵢₜₕ, and the aluminum oxide has a number distribution of the grain sizes having a median d₅₀, an arithmetic mean dₐᵣᵢₜₕ and a symmetry value S(Al₂O₃)=d₅₀/dₐᵣᵢₜₕ, where S(Al₂O₃) and S(Cu) satisfy the following condition:

0.7≤S(Al₂O₃)/S(Cu)≤1.4.

More preferably, S(Al₂O₃) and S(Cu) satisfy the following condition:

0.74≤S(Al₂O₃)/S(Cu)≤1.35;

even more preferably the following condition

0.80≤S(Al₂O₃)/S(Cu)≤1.25.

The thermal shock resistance of the copper-ceramic composite can be improved in this way.

In a preferred embodiment, the average grain shape factor of the aluminum oxide Rₐ(Al₂O₃) and the average grain shape factor of the copper or copper alloy Rₐ(Cu) satisfy the following condition 0.5≤Rₐ(Al₂O₃)/Rₐ(Cu)≤2.0.

Even more preferably

0.75≤Rₐ(Al₂O₃)/Rₐ(Cu)≤1.5

And even more preferably

0.80≤Rₐ(Al₂O₃)/Rₐ(Cu)≤1.20.

A further optimization in the thermal shock resistance of the copper-ceramic composite can be realized in this way.

In a preferred embodiment, the aluminum oxide has grain sizes in the range from dₘᵢₙ(Al₂O₃) to dₘₐₓ(Al₂O₃), the copper or the copper alloy has grain sizes in the range from dₘᵢₙ(Cu) to dₘₐₓ(Cu),

and the ratios of dₘᵢₙ(Al₂O₃) to dₘₐₓ(Cu) and of dₘₐₓ(Al₂O₃) to dₘᵢₙ(Cu) satisfy the conditions (i) and (ii) below:

dₘᵢₙ(Al₂O₃)/dₘₐₓ(Cu)≥1×10⁻⁵ and (i)

2.5≥dₘₐₓ(Al₂O₃)/dₘᵢₙ(Cu). (ii)

Even more preferably, the ratios of dₘᵢₙ(Al₂O₃) to dₘₐₓ(Cu) and of dₘₐₓ(Al₂O₃) to dₘᵢₙ(Cu) satisfy the conditions (i) and (ii) below:

dₘᵢₙ(Al₂O₃)/dₘₐₓ(Cu)≥0.001 and (i)

1.5≥dₘₐₓ(Al₂O₃)/dₘᵢₙ(Cu); (ii)

and most preferably the conditions (i) and (ii) below:

dₘᵢₙ(Al₂O₃)/dₘₐₓ(Cu)≥0.002 and (i)

1.0≥dₘₐₓ(Al₂O₃)/dₘᵢₙ(Cu). (ii)

In a particularly preferred embodiment

0.005≥dₘᵢₙ(Al₂O₃)/dₘₐₓ(Cu)≥0.002 and (i)

1.0≥dₘₐₓ(Al₂O₃)/dₘᵢₙ(Cu)≥0.05. (ii)

A strong bond between the metal coating and the ceramic substrate which also withstands frequent temperature change stresses can be realized in this way. Preference is given, as mentioned above, to dₘᵢₙ(Cu) being ≥10 μm and dₘₐₓ(Cu) being ≤300 μm, more preferably dₘᵢₙ(Cu) being ≥15 μm and dₘₐₓ(Cu) being ≤250 μm, even more preferably dₘᵢₙ(Cu) being ≥20 μm and dₘₐₓ(Cu) being ≤210 μm, where dₘᵢₙ(Cu) and dₘₐₓ(Cu) are the minimum and maximum grain sizes of the copper.

The present invention further provides a module containing at least one metal-ceramic composite as described above and one or more bond wires. The bond wire or the bond wires is/are usually joined to the coating composed of copper or copper alloy. Suitable bonding methods for joining wires to a metal coating are known to those skilled in the art. The module can additionally contain one or more electronic components such as one or more chips.

The grain structures of the aluminum oxide of the ceramic substrate and also of the copper or of the copper alloy of the metal coating are determined as follows for the purposes of the present invention:

### Grain Size Distribution of the Aluminum Oxide of the Ceramic Substrate

A scanning electron micrograph (SEM image) is taken of the surface of the ceramic substrate. A special specimen preparation in the form of a polished section is not necessary. The SEM image is taken on one place on the ceramic substrate which had previously been covered with copper and exposed by etching.

The grain sizes are determined by means of a line intercept method. Line intercept methods are known to those skilled in the art and are described, for example, in ASTM 112-13.

The magnification is selected so that at least 50 Al₂O₃ grains are intersected by the pattern of lines. If the ceramic substrate also contains grains having a different chemical composition, for example ZrO₂ grains, these can readily be distinguished from the Al₂O₃ grains in the SEM image by means of secondary electron contrast and are thus not included in the subsequent calculations.

For the purposes of the present invention, two parallel lines are drawn in the x direction and two parallel lines are drawn in the y direction in the optical micrograph. The lines divide the image into three strips of equal width. This is schematically shown in FIG. 3. When a grain is intersected over a length L by one of these lines, this length L is taken as the grain size. A grain size is thus obtained for each grain intersected by one of these lines. At the crossing point of two lines, two values are obtained for one grain, and both of these go into the determination of the grain size distribution.

A grain size distribution is obtained from the grain sizes of the intersected grains, and from this distribution it is in turn possible to determine the d₅, d₅₀ and d₉₅ values and also the arithmetic mean dₐᵣᵢₜₕ.

As is explained above and generally known to a person skilled in the art, the following applies to the d₅₀, frequently also referred to as median: 50% of the grains have a diameter which is smaller than the d₅₀. In an analogous way, the d₅ is the value at which 5% of the grains have a diameter which is smaller than this d₅, and the d₉₅ is the value at which 95% of the grains have a diameter which is smaller than this d₉₅.

The arithmetic mean of the grain size distribution is given by the sum of the grain sizes of the individual grains divided by the number of intersected grains.

### Grain Size Distribution of the Copper or the Copper Alloy

An optical micrograph is taken of the surface of the coating composed of copper or a copper alloy (parallel to the coated substrate surface). Special specimen preparation in the form of a polished section is not necessary.

The grain sizes are determined by a line intercept method. Line intercept methods are known to those skilled in the art and are described, for example, in ASTM 112-13.

The magnification is selected so that at least 50 grains are intercepted by the pattern of lines.

As regards the further evaluation by the line intercept method, reference may be made to what has been said above in the case of aluminum oxide.

Both the grain sizes of the copper or the copper alloy and also the grain sizes of the Al₂O₃ are thus determined in a plane which runs parallel to the coated substrate surface or is coplanar with the latter.

### Shape Factor of Individual Grains, Average Grain Shape Factor

### Aluminum Oxide

The SEM image which was used in the determination of the grain size distribution is employed.

To determine the shape factor of an individual grain, the following procedure is employed:

The longest dimension d_{K,max} thereof is determined. The grain diameter d_{K,ortho} running perpendicular to d_{K,max} is subsequently determined on half the length of d_{K,max}. The shape factor of the individual grain R_{K} is given by the ratio of d_{K,ortho} to d_{K,max}, i.e. R_{K}=d_{K,ortho}/d_{K,max}. This is shown schematically in FIG. 4 for a grain having an elliptical grain structure. The more the shape of a grain in its two-dimensional projection approaches that of a circle, the more does the shape factor of the grain approach the value 1.0. The shape factor is therefore also a measure of the circularity/roundness of the grains.

The shape factor is determined for at least 50 grains in the SEM image. The grains which were also intercepted by the lines in the line intercept method are usually evaluated.

The average grain shape factor of the aluminum oxide is then given by the arithmetic mean of the shape factors of the individual Al₂O₃ grains (i.e. the total of the individual shape factors divided by the number of grains examined).

### Copper, Copper Alloy

The optical micrograph which was used in the determination of the grain size distribution is employed.

With regard to the determination of the shape factor of the individual grains and also of the average grain shape factor of the copper or the copper alloy, reference may be made to what has been said above in the case of Al₂O₃.

Both the grain shape factors of the copper or of the copper alloy and also the grain shape factors of the Al₂O₃ are thus determined in a plane which runs parallel to the coated substrate surface or is coplanar with the latter.

A bonding process which is preferably used for producing the copper-ceramic substrates of the invention is described below:

A typical process which is preferably used in the context of the present invention for applying the copper coating to the ceramic substrate is, for example, known from the documents U.S. Pat. No. 3,744,120, U.S. Pat. No. 3,994,430, EP 0 085 914 A or DE 23 19 854 A, the corresponding disclosure of which is incorporated by reference into the present invention.

It is common to all the production processes disclosed there, for example in the form of the direct copper bonding process (DCB process), that a copper foil is firstly oxidized in such a way that an essentially uniform copper oxide layer is obtained. The resulting copper foil is then positioned on a ceramic substrate and the composite of ceramic substrate and copper foil is heated to a process or bonding temperature in the range from about 1025 to 1083° C., as a result of which a metallized ceramic substrate is formed. After bonding, the copper foil thus represents a coating. Finally, the resulting metallized ceramic substrate is cooled.

The joining of ceramic substrate and copper foil is carried out in a furnace, with bonding furnaces generally being used. Corresponding bonding furnaces, frequently also referred to as tunnel kilns, comprise, inter alia, an elongated tunnel-like furnace space (also referred to as a muffle) and a transport device having a transport element, for example in the form of a flexible and heat-resistant conveyor belt for transporting the material being treated through the furnace space which is heated by means of a heating device. The ceramic substrates are positioned together with the copper foil on a support on the conveyor belt and subsequently run, driven by the conveyor belt, through a heating region in which the required bonding temperature is attained in the bonding furnace. At the end of the bonding process, the resulting composite of ceramic substrate and copper foil according to the invention is cooled again.

This process can in principle be employed for producing ceramic substrates metallized on one side and also for producing substrates metallized on both sides. The production of substrates metallized on both sides is generally carried out by a two-stage bonding process, i.e. by means of a two-stage single layer process (SLB process). In the context of the invention, preference is given to using a two-stage bonding process.

In this two-stage bonding process for producing ceramic substrates metallized on both sides according to the invention, the ceramic is joined to the copper foils on the opposite sides of the ceramic substrate in two passes through the furnace.

For this purpose, a ceramic substrate is firstly positioned on a support and subsequently covered with a copper foil on the upper side, i.e. on the side facing away from the support. As a result of the action of heat, this side of the ceramic substrate is joined to the metal layer and the resulting arrangement is subsequently cooled.

The substrate is subsequently turned over and the other side of the substrate is provided in the same way with a metal layer, i.e. the copper foil, in a second bonding step.

It is possible to produce individual cards or large cards which have a plurality of individual cards which can be broken out.

### EXAMPLES

The following examples show how the grain structure of the aluminum oxide in the ceramic substrate influences the mechanical strength and the thermal conductivity of a copper-ceramic composite.

Five copper-ceramic specimens were produced by a DCB process and differed in their grain size distributions of the aluminum oxide in the ceramic substrate:

Copper-ceramic composite 1, hereinafter “K-K-V 1” (according to the invention)
Copper-ceramic composite 2, hereinafter “K-K-V 2” (comparative specimen)
Copper-ceramic composite 3, hereinafter “K-K-V 3” (comparative specimen)
Copper-ceramic composite 4, hereinafter “K-K-V 4” (comparative specimen)
Copper-ceramic composite 5, hereinafter “K-K-V 5” (comparative specimen)

In each of these five copper-ceramic composites, both the upper side and also the underside of the ceramic substrate were provided with a copper coating. The copper coating was firstly bonded by means of the SLB process to one side of the ceramic substrate. The opposite side of the ceramic substrate was subsequently provided by means of the SLB process with a further copper coating so as to form a copper-ceramic substrate in which a copper foil is bonded to each of the two sides of the ceramic. One of the two copper coatings on each of the specimens was subsequently structured by an etching process (same structuring for all specimens). In all three examples, the substrates comprised 96% by weight of Al₂O₃, but differed in their grain structure.

In each of these five copper-ceramic composites, the ceramic substrate had the following dimensions:

Thickness of the ceramic substrate: 0.38 mm;
Length×width of the ceramic substrate: 190×140 mm²

The copper coating in each case had a thickness of 0.3 mm.

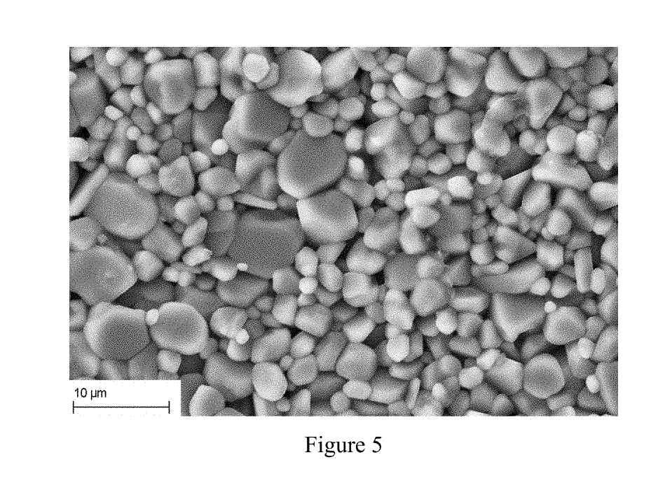

FIG. 5 shows an SEM image of the surface of the ceramic substrate of K-K-V 1, by means of which the Al₂O₃ grain sizes of the working example K-K-V 1 were determined.

Grain size ranges and symmetry values of the grain size distributions of the Al₂O₃ in the specimens K-k-V-1 to K-K-V 5 are listed in table 1.

For each of these five specimens, determinations were made both of the flexural fracture strength and of the thermal conductivity of the ceramic substrate in the copper-ceramic composite.

In the determination of the flexural fracture strength the force resulting in fracture was determined via three-point bending. The measurement was based on DIN EN 843-1 (2008), with the specimen geometry differing from the DIN EN 843-1 (2008) in that the specimens had dimensions of 20×40×0.38 mm³ or 20×40×0.63 mm³.

The results are summarized in table 1 below:

TABLE 1
Mechanical strength and thermal conductivity of the
ceramic substrate of the copper-ceramic composite

| | | Mechan- | Thermal |
|---|---|---|---|
| | | ical | conduc- |
| | | strength | tivity |
| Specimen K-K-V | Grain size range: 0.63-13.3 μm | ++ | ++ |
| 1 (according to | Symmetry value d₅₀/dₐᵣᵢₜₕ: 0.86 | | |
| the invention) | | | |
| Specimen K-K-V | Grain size range: 0.74-15.1 μm | ++ | − |
| 2 (comparison) | Symmetry value d₅₀/dₐᵣᵢₜₕ: 0.66 | | |
| Specimen K-K-V | Grain size range: 0.58-9.7 μm | − | ++ |
| 3 (comparison) | Symmetry value d₅₀/dₐᵣᵢₜₕ: 1.31 | | |
| Specimen K-K-V | Grain size range: 3.1-28.4 μm | + | + |
| 4 (comparison) | Symmetry value d₅₀/dₐᵣᵢₜₕ: 0.84 | | |
| Specimen K-K-V | Grain size range: 0.003-1.49 μm | +++ | − |
| 5 (comparison) | Symmetry value d₅₀/dₐᵣᵢₜₕ: 0.85 | | |

Additionally, the effect of the breadth of the grain size distribution of the aluminum oxide on mechanical strength and thermal conductivity was investigated. The results are shown by table 2.

TABLE 2
Effect of the breadth of the Al₂O₃ grain size distribution

| Breadth of Al₂O₃ | | |
|---|---|---|
| Distribution d₅/d₉₅ | Mechanical strength | Thermal conductivity |
| 0.24 | + | + |
| 0.03 | + | − |
| 0.61 | − | + |

As table 2 shows, a further optimization of mechanical strength and thermal conductivity on the part of the ceramic substrate can be achieved if the breadth of the grain size distribution is within the range according to the invention.

1. A copper-ceramic composite comprising
a ceramic substrate containing aluminum oxide, wherein the aluminum oxide
has grain sizes in the range from 0.01 μm to 25 μm and
has a number distribution of the grain sizes with a median value d₅₀ and an arithmetic mean dₐᵣᵢₜₕ, and the ratio of d₅₀ to dₐᵣᵢₜₕ is in the range from 0.75 to 1.10, and
a coating composed of copper or a copper alloy present on the ceramic substrate.

2. The copper-ceramic composite of claim 1, wherein the ratio of d₅₀ to dₐᵣᵢₜₕ is in the range from 0.78 to 1.05, more preferably in the range from 0.80 to 1.00.

3. The copper-ceramic composite of claim 1, wherein the aluminum oxide has a number distribution of the grain sizes with a d₅ value and a d₉₅ value, and the ratio d₅ to d₉₅ is in the range from 0.1 to 0.4, more preferably in the range from 0.11 to 0.35, even more preferably in the range from 0.12 to 0.30.

4. The copper-ceramic composite of claim 1, wherein the grain sizes of the aluminum oxide are in the range of 0.3 μm to 23 μm, more preferably in the range of 0.5 μm to 20 μm.

5. The copper-ceramic composite of claim 1, wherein the ceramic substrate contains the aluminum oxide in an amount of at least 65% by weight.

6. The copper-ceramic composite of claim 1, wherein the coating composed of copper or a copper alloy is applied by a DCB process to the ceramic substrate.

7. The copper-ceramic composite of claim 1, wherein the coating composed of copper or a copper alloy at least partly has structuring to form electrical contact areas.

8. The copper-ceramic composite of claim 1, wherein the coating composed of copper or a copper alloy has a thickness in the range of 0.2-1.2 mm over at least 70% of its area; and/or the ceramic substrate has a thickness in the range of 0.2-1.2 mm over at least 70% of its area.

9. A module containing at least one copper-ceramic composite according to claim 1 and one or more bond wires.
